(19) United States
(12) Patent Application Publication
(10) Pub. No.: US 2009/0027844 A1
(43) Pub. Date: Jan. 29, 2009

(54) TRANSLATOR FOR SUPPORTING DIFFERENT MEMORY PROTOCOLS

(76) Inventors: Hau Jiun Chen, Singapore (SG); Martin Goldstein, Campbell, CA (US); Lidia Warnes, Roseville, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/781,346

(22) Filed: Jul. 23, 2007

(51) Int. Cl. H05K 5/00; G06F 1/16; H05K 7/00

(52) U.S. Cl. 361/684

(57) ABSTRACT

A computer system includes a printed circuit board (PCB) that includes a first external interface for memory connection thereto, the first external interface employs a first memory protocol. The computer system further includes an extension circuit board and a translator module. the extension circuit board includes a second external interface for memory connection thereto and a third external interface, wherein the second external interface employs a second memory protocol different from the first memory protocol. The translator module is connectable to the first external interface of the PCB and the third external interface of the extension circuit board to provide translation between the first and second memory protocols.

### RELATED APPLICATIONS

This application is related to U.S. patent application Ser. No. 11/789,545, filed on Apr. 25, 2007, and entitled, “SERIAL CONNECTION EXTERNAL INTERFACE FROM PRINTED CIRUIT BOARD TRANSLATION TO PARALLEL MEMORY PROTOCOL.” This application is also related to U.S. patent application Ser. No. 11/789,632, filed on Apr. 25, 2007, and entitled, “SERIAL CONNECTION EXTERNAL INTERFACE RISER CARDS AVOIDANCE OF ABUTMENT OF PARALLEL CONNECTION EXTERNAL INTERFACE MEMORY MODULES.” The disclosures of these applications are hereby incorporated by reference in their entireties.

### BACKGROUND

DIMM (dual in-line memory module) technology has random access memory (RAM) integrated circuits (ICs) mounted on a printed circuit board (PCB), such as a motherboard or a system circuit board in a computer system. Examples of a computer system include a personal computer or PC, server, a mainframe, etc. Various types of DIMMs exist. For example, DDR SDRAM (Double Data Rate Synchronous Dynamic Random Access Memory) DIMM technology, including DDR, DDR2, and DDR3 versions, has a parallel external interface. Thus, a DDR SDRAM may be mounted and electrically coupled to a PCB through connectors on the PCB that operate as parallel-connection external interfaces. Fully buffered DIMM or FB-DIMM technology, on the other hand, has a serial external interface. Thus, a FB-DIMM may be mounted and electrically coupled to a PCB through connectors on the PCB that operate as serial-connection external interfaces. FB-DIMM technology employs an Advanced Memory Buffer (AMB) having a serial connection to a memory controller, and a parallel connection to a dynamic random access memory (DRAM). The AMB on each FB-DIMM translates the communication in serial point-to-point link protocol received from the memory host controller to DDR SDRAM parallel protocol that is transmitted to the DRAMs as read, write, refresh, etc. operations within the DIMM.

### BRIEF DESCRIPTION OF THE DRAWINGS

Embodiments are illustrated by way of example and not limited in the following figure(s), in which like numerals indicate like elements, in which:

FIG. 1 illustrates a computer system with a translator device structure, according to an embodiment.

FIG. 2 illustrates a perspective view of the same computer system shown in FIG. 1, according to an embodiment.

FIG. 3 illustrates a method for upgrading or modifying from a first memory protocol implementation to a second memory protocol implementation in a computer system, according an embodiment.

### DETAILED DESCRIPTION

For simplicity and illustrative purposes, the principles of the embodiments are described by referring mainly to examples thereof. In the following description, numerous specific details are set forth in order to provide a thorough understanding of the embodiments. It will be apparent however, to one of ordinary skill in the art, that the embodiments may be practiced without limitation to these specific details. In other instances, well known methods and structures have not been described in detail so as not to unnecessarily obscure the embodiments.

As noted earlier, while the FB-DIMM has internal memory with parallel connections, its external interface is a serial connection. With DDR3 SDRAM being a successor to DDR2 SDRAM in DDR memory standards, computer system boards with FB-DIMM connectors currently embedded are not operable to support DDR3 SDRAM DIMMs. That is because the serial memory connections and serial data transfer technology (hereinafter, cumulatively, “serial memory protocol”) of FB-DIMM connectors are fundamentally different from the parallel memory connections and parallel data transfer technology (hereinafter, cumulatively, “parallel memory protocol”) of DDR3 SDRAM DIMM connectors. Therefore, it is desirable to have different memory technologies to be used in a same computer system with minimal cost added to the initial design or subsequent modification of the computer system board or PCB. For example, it is desirable to enable a computer system having a PCB with existing serial-connection external interfaces (e.g., FB-DIMM connectors) to also accept parallel-connection memory modules (e.g., DDR3 SDRAM DIMMs) for memory upgrade or memory extension purposes.

As referenced above, previously-filed U.S. patent application Ser. Nos. 11/789,545 and 11/789,632 describe a number of embodiments for a translator riser board or card having a FB-DIMM-to-DDR3 SDRAM translator integrated circuit (IC) and DDR3 SDRAM DIMM connectors. Such a translator board or card may be connected to an existing FB-DMM connector on a PCB to enable the PCB to accept and use DDR3 SDRAM DIMMs as connected to DDR3 SDRAM DIMM connectors on the translator board.

Accordingly, described herein are alternative embodiments for a translator device that is operable to support the implementation of memory modules of one memory technology (e.g., DDR3 SDRAM DIMMs with parallel-connection technology) on PCBs that have embedded connectors for another memory technology (e.g., FB-DIMMs with serial-connection technology). Such a translator device serves to communicatively interconnect or bridge the different memory technologies so as to reduce modification time, labor, and materials through employment of a single memory technology, such as FB-DIMM, on the PCB while at the same time increasing or upgrading a memory capacity of the PCB.

Various embodiments as described herein provide a translator device structure that includes at least one translator module or card and an extension circuit board. The translator module serves as a bridge between a PCB of the computer system and the extension circuit board. It connects directly to the PCB on an intersecting plane (e.g., substantially vertical or orthogonal) to the PCB plane. It also connects directly to the extension circuit board on an intersecting plane (e.g., substantially vertical or orthogonal) to the plane of the extension circuit board. As its name implies, the translator module provides translation between different memory technologies connected thereto. With the computer system PCB acting as a motherboard, the extension circuit board acts as a daughterboard or a mezzanine board that is arranged substantially parallel to the motherboard. The mezzanine board allows the addition of memory modules thereon that may be used by the main PCB, wherein the additional memory modules employ a memory technology different from that employed by the PCB and translation between the different memory technologies is provided by the translator module.

Accordingly, in one embodiment, the translator device structure is modular to a computer system so that it may be incorporated into the computer system as a part of the computer system and subsequently removable from the computer system without corrupting operations of the computer system. In another embodiment, the translator device structure is modular to a computer system such that it is not a part of the computer system but serves as an optional add-on to the computer system to provide an extension for implementation of an additional memory technology.

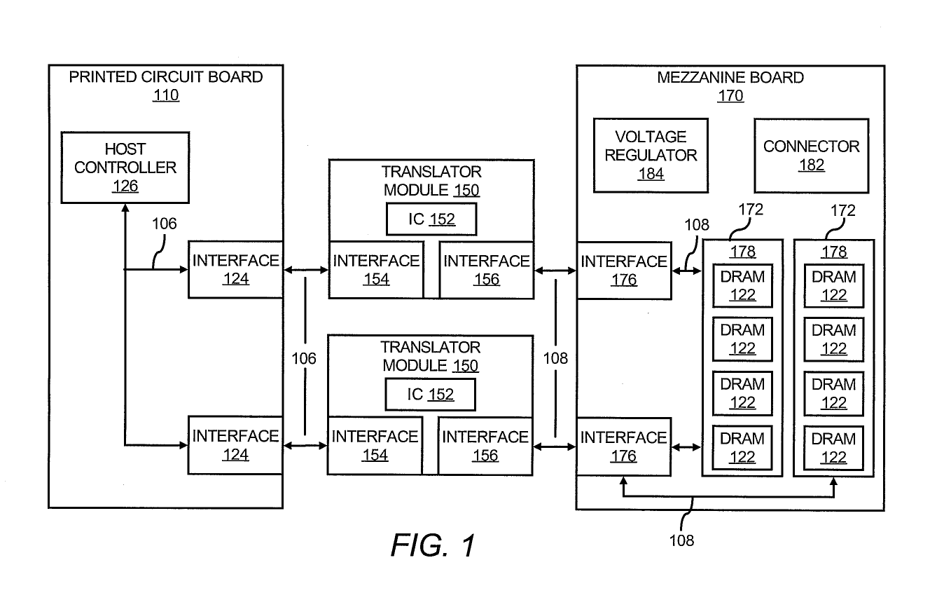

FIG. 1 illustrates a block diagram of a computer system 100 having a PCB 110 such as a motherboard, a translator device structure that includes one or more translator modules or cards 150, a mezzanine board or card 170 in proximity or near the PCB 110, one or more serial protocol buses 106, and one or more parallel protocol buses 108. Examples of a serial protocol bus 106 include a FB-DIMM bus, a PCI-express bus, a HTx bus, or any other high-speed serial bus. An example of a parallel protocol bus 108 is a DDR-type bus, such as a DDR3 bus. Also, although FIG. 1 is described with reference to a translation between FB-DIMM protocol as the serial memory protocol and DDR3 protocol as the parallel memory protocol, it should be understood that such a description is applicable to a translation between any serial and parallel memory protocols.

For simplicity, FIG. 1 does not illustrate other components that are typically included in a computer system. Examples of such components include secondary memory devices for long-term storage, user interfaces, and network interfaces. A secondary memory device may include a computer readable medium (CRM) for storing software programs, applications, or modules for execution by the computer system 100. An example of a CRM includes a hard disk drive or tape drive that may be an electronic, optical, or magnetic drive. A user interface may include one or more input devices, such as a keyboard, a mouse, a stylus, and the like. A user interface also may include one or more output devices, such as a display adapter, a computer monitor, and the like. A network interface, such as an Ethernet port, allows the computer system 100 to communicate with other computer systems via, for example, a network such as the Internet or a private intranet.

The PCB 110 includes a serial protocol interface 124 and a memory or host controller 126. In one example, the serial protocol interface 124 includes FB-DIMM connectors, each having slots or holes that are operable to receive, engage, mesh, couple, connect, or otherwise mate with the interface 154 of a translator module 150 or a contacting interface of a FB-DIMM. The host controller 126 includes one or more processors to provide an execution platform for executing software. Thus, the host controller 126 includes one or more single-core or multi-core processors of any of a number of computer processors, such as processors from Intel, AMD, and Cyrix. As referred herein, a computer processor may be a general-purpose processor, such as a central processing unit (CPU) or any other multi-purpose processor or microprocessor. A computer processor also may be a special-purpose processor, such as a graphics processing unit (GPU), an audio processor, a digital signal processor, or another processor dedicated for one or more processing purposes. The host controller 126 accesses and communicates with memory modules via the serial bus 106 and the serial protocol interface 124.

Each translator module 150 includes a serial protocol interface 154, a parallel protocol interface 156, and an integrated circuit (IC) 152. In one example, the serial protocol interface 154 includes pins, leads, contacts, or fingers that comply with standards of the JEDEC Solid State Technology Association (previously known as the Joint Electron Device Engineering Council; World Wide Web jedec.org). The translator module 150 may be connected to the PCB 110 by inserting the pins, leads, contacts, or fingers of the serial protocol interface 154 (of the translator module 150) into the slots or holes of the FB-DIMM connectors that make up the serial protocol interface 154 (of the PCB 110). The translator module 150 may draw power from the PCB 110, via the interfaces 124 and 154, to support its operations. In one example, the parallel protocol interface 156 also includes pins, leads, contacts, or fingers that comply with standards of the JEDEC Solid State Technology Association (previously known as the Joint Electron Device Engineering Council; World Wide Web jedec.org). The translator module 150 may be connected to the mezzanine board 170 by inserting the pins, leads, contacts, or fingers of the parallel protocol interface 156 (of the translator module 150) into the slots or holes that make up a parallel protocol interface 176 (of the mezzanine board 170).

In one example, the IC 152 is operable to receive commands and read/write data from the host controller 126 and to send read/write data back to the host controller 126 using the FB-DIMM protocol as a serial memory protocol. The IC 152 is also operable to translate the FB-DIMM protocol as the serial memory protocol to DDR3 protocol as a parallel memory protocol to send transfer commands and read/write data to the mezzanine board 170. Vice versa, the IC 152 is further operable to translate the DDR3 protocol as the parallel memory protocol to send read/write data from the mezzanine board 170 to the host controller 126 of the PCB 110. Any known IC that provides translation between FB-DIMM protocol and DDR3 protocol may be implemented as the IC 152.

The mezzanine board 170 includes a plurality of parallel protocol interfaces 176 for connection to a plurality of translator modules 150, as described above. It also includes a plurality of parallel protocol interfaces 172 for connection of a plurality of parallel protocol memory modules 178 thereon. In one example, as illustrated in FIG. 1 and not to be limiting thereof, each parallel protocol interface 172 is a DDR3 SDRAM connector that includes slots or holes to receive, engage, mesh, couple, connect, or otherwise mate with a DDR3 SDRAM memory module as a parallel protocol memory module 178. Each DDR3 SDRAM memory module 178 includes pins, leads, contacts, or fingers as a parallel protocol interface that comply with standards of the JEDEC Solid State Technology Association (previously known as the Joint Electron Device Engineering Council; World Wide Web jedec.org). A DDR3 SDRAM memory module 178 may be connected to the mezzanine board 170 by inserting the pins, leads, contacts, or fingers of its parallel protocol interface into the slots or holes of a DDR3 SDRAM connector that makes up an interface 172 on the mezzanine board 170. In one example, as illustrated in FIG. 1 and not to be limiting thereof, each DDR3 SDRAM memory modules 178 includes, for example, a plurality of DRAM devices as parallel memory devices 122. Accordingly, read/write data to and from the mezzanine board 170 for translation by an IC 152 in a translator module 150 is sent from and received by, via a parallel bus 108, a DDR3 SDRAM memory module 178 at a connector 172.

The mezzanine board 170 optionally includes a connector 182 and one or more voltage regulator modules 184. In one example, the connector 182 receives or couples with a flying lead cable (not shown) to deliver additional power from a power supply (not shown) in the computer system 100 to the voltage regulator module 184. The connector 182 may be located at any desirable, selected, and/or convenient place on the mezzanine board 170. The voltage regulator module 204 may be located on the mezzanine board 170 so as to provide additional, extra, or sufficient power to the components onboard or connected with the mezzanine board 170. The voltage regulator module 184 is also operable to generate component and/or bus voltages.

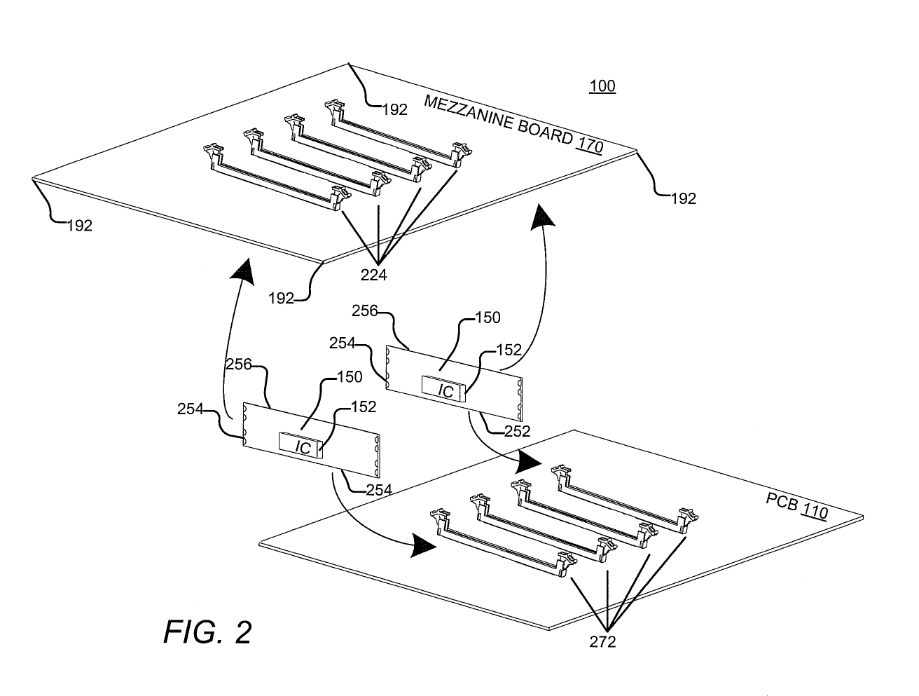

FIG. 2 illustrates a perspective view of the PCB 110, a mezzanine board 170, and one or more translator modules 150. In one example, as illustrated, the PCB 110 includes one or more FB-DIMM connectors 272 as the serial protocol interface 124 (FIG. 1). For illustrative purposes, only four FB-DIMM connectors 272 are shown. However, it should be understood that any desired practical number of FB-DIMM connectors 272 may be mounted on the PCB 110. As also illustrated, in one example, the mezzanine board 170 includes one or more DDR (or DDR2 or DDR3) connectors 224 as the parallel protocol interface 172 (FIG. 1) for receiving memory modules 178 (FIG. 1). For illustrative purposes, only four DDR connectors 224 are shown to correspond with the number of FB-DIMM connectors 272 on the PCB 110. However, it should be understood that any desired practical number of DDR connectors 224 may be mounted on the mezzanine board 170 and they do not have to correspond to the number of connectors 272 on the PCB 110.

As further illustrated, in one example, one or more translator modules 150 are used to bridge the PCB 110 and the mezzanine board 170. Each translator module 150 includes an IC 152 to provide translation between the different memory technologies employed on the two boards. One edge 254 of each translator module 150 includes pins, leads, contacts, or fingers of a serial protocol interface 154 (FIG. 1) for inserting into a connector 272 of the PCB 110. The other edge 256 of each translator module 150 includes pins, leads, contacts, or fingers of a parallel protocol interface 156 (FIG. 1) for inserting into a connector of the parallel protocol interface 176 (FIG. 1) of the mezzanine board 170. Such a connector is not visible in FIG. 2 because it is on the underside of the mezzanine board 170. A plurality of connectors of the parallel protocol interface 176 may be mounted on the underside of the mezzanine board 170 and with locations offset from the locations of the connectors 224 on the other side so that the two set of connectors do not interfere with one another. Each translator module 150 also includes notches 254 at both ends to allow the translator module 150 to be accommodated by end latches on the connectors 224 and the connectors on the underside of the mezzanine board 170.

FIG. 2 illustrates the translator modules 150 connected to the PCB 110 and mezzanine board 170 in a substantial vertical or orthogonal direction to both boards. Alternative embodiments are contemplated, wherein the translator modules 150 may be connected to the parallel planes of the PCB 110 and mezzanine board 170 at any intersecting plane to such parallel planes, so long as the connectors on both boards are correspondingly angled to accommodate the intersecting plane of the translator modules 150. For illustrative purposes, only two translator modules 150 are shown. However, it should be understood that any desired number of translator modules 150 may be used so long as there are corresponding numbers of connectors for the parallel protocol interface 176 on the mezzanine board 170 and connectors 272 on the PCB 110 for connections to the translator modules 150.

The mezzanine board 170 may be secured and aligned in a position parallel to the PCB 110 by virtue of its connection to the translator module 150, which is securely connected to the PCB 110 via the connectors 272. Optionally, additional securing mechanisms may be mounted on either or both the PCB 110 and the mezzanine board 170 to further secure and align the mezzanine board 170 in place so as to allow the translator modules 150 to be connected to the connectors on both boards. For example, the mezzanine board 170 includes fasteners such as screws or binding posts at the four corners 192 such that such fasteners are aligned with predetermined locations on the PCB 110 for attachment thereto and for further alignment of the translator module 150 to the connectors of the parallel protocol interface 176 as mounted on the underside of the mezzanine board 170. It should be noted that FIG. 2 is not drawn to scale and does not include other components that may mounted on the PCB 110, the mezzanine board 170, and the translator modules 150 so as to more clearly illustrate the translator modules 150, the connectors 272 on the PCB 110, and the connectors 224 on the mezzanine board 170.

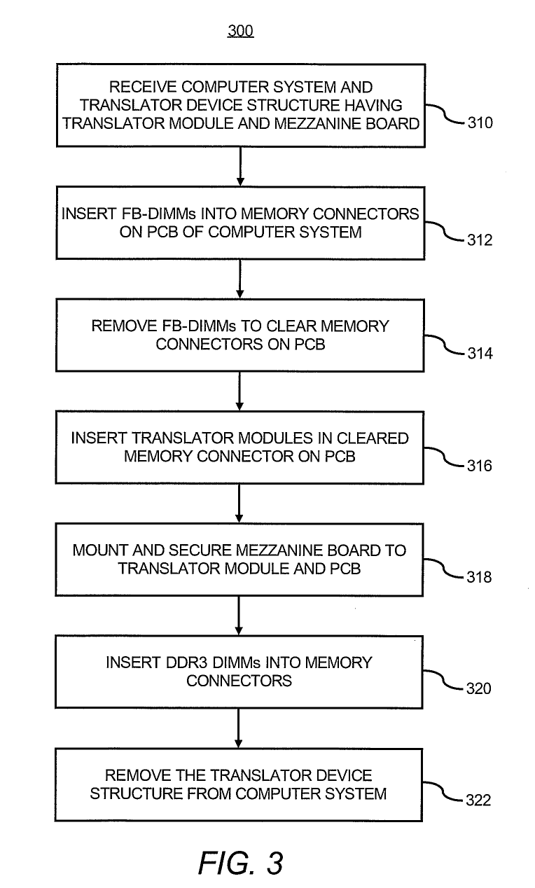

FIG. 3 illustrates a method or process 300 for upgrading or modifying from a first memory protocol implementation in a PCB of a computer system to a second memory protocol implementation outside of the PCB, in accordance with one embodiment. For illustrative purposes and not to be limiting thereof, the method 300 is discussed in the context of the computer system 100 as illustrated in FIGS. 1 and 2. Also for discussion purposes, the first memory protocol is a serial memory protocol (e.g., FB-DIMM), and the second memory protocol is a parallel memory protocol (e.g., DDR3-DIMM), or vice versa. That is, FIG. 3 illustrates, as an example, the specific use of FB-DIMMs and DDR3-DIMMs. However, it should be understood that the method 300 is applicable for any serial protocol memory modules other than FB-DIMMs and for any parallel protocol memory modules other than DDR3 DIMMs. The method 300 may be performed by a user as exemplified above.

At 310, the computer system 100 and a translator device structure are received separately, wherein the translator device structure includes one or more translator modules 150 and the mezzanine board 170.

At 312, the user inserts one or more FB-DIMMs into the connectors 272 for use by the PCB 110 and the computer system 100.

At 314, the user removes one or more FB-DIMM modules to make available one or more connectors 272 on the PCB 110. It should be understood that steps 312 and 314 are optional. In an alternative embodiment, the user may not have any FB-DIMMs inserted in the connectors 272 in the first instance and may wish to proceed directly to step 316 to upgrade or modify the memory implementation by the PCB 110 without any need for FB-DIMM removal. Thus, only when the user has previously installed a FB-DIMM into a connector 272 and desires to use that same connector 272 for a translator module 150, then the user would desire to remove the FB-DIMM to make room for the translator module 150.

At 316, to upgrade or modify memory implementation by the PCB 110, the user inserts one or more translator modules 150 into the available one or more connectors 272. The translator modules 150 allow the computer system to implement serial protocol memory inside the PCB as well as parallel protocol memory outside the PCB. The number of translator modules 150 depend on how many DDR3-DIMMs the user desires for use by the computer system 100 and how many DDR3-DIMMs each translator module 150 is tasked to handle. For example, if each translator module 150 is tasked to handle translation for two DDR3-DIMMs, and the user desires to use 4 DDR3-DIMMs to be connected to the connectors 224 of the mezzanine board 170, the user would insert two translator modules 150 into two of the four connectors 272 as illustrated in FIG. 2. The user has the option of leaving the remaining two connectors empty for inserting one or two FB-DIMMs into those two connectors.

At 318, the user mounts and secures the mezzanine board 170 so as to align the board 170 in parallel to the PCB 110 for proper connections of the one or more translator modules 150 to the connectors on underside of the mezzanine board 170 as noted earlier. The alignment and secure placement of the mezzanine board 170 may be assisted by fasteners located at the four corners of the mezzanine board 170 and corresponding locations on the PCB 110 that may be used for attachment of such fasteners.

At 320, the user inserts one or more DDR3 DIMMs into the connectors 224 as mounted on the mezzanine board 170, whereby the one or more translator modules 150 provide translation of the parallel memory protocol implementation of DDR3 DIMMs to serial memory protocol implementation for the PCB to use the DDR3 DIMMs.

At 322, the user has the option to remove the mezzanine board 170 to reconfigure the connections at the connectors 272 on the PCB 110 to insert or remove any FB-DIMMs or translator modules 150 connected thereto.

Accordingly, the use of a translator device structure that includes one or more translator module 150 and a mezzanine board 170 allows the computer system 100 and its PCB 110 therein to accept more than one type of memory technologies. The incorporation of such a translator device structure in a computer system also allows the computer system to be field upgraded to accommodate additional memory modules of a memory technology different from that originally factory-provided on the PCB 110 of the computer system. Thus, the computer system 100 may be shipped to a customer with the translator device structure (which includes one or more translator modules 150 and the mezzanine board 170) optionally and separately provided from the PCB 110 and the rest of the computer system 100. The PCB 110 employs a serial memory technology such as FB-DIMM, and the mezzanine board 170 employs a parallel memory technology such as DDR3 DIMM. Through field installation of the translator device structure, a user, such as the consumer, an on-site service technician or provider, or an in-shop service technician or provider, now has the ability to choose between serial and parallel memory technologies without loss in a total quantity of DDR3 DIMM modules and FB-DIMM modules allowable in the computer system 100. Thus, no additional investment or modification is required for the PCB 110 to allow use of DDR3 memory technology in the computer system 100.

What has been described and illustrated herein is an embodiment along with some of its variations. The terms, descriptions and figures used herein are set forth by way of illustration only and are not meant as limitations. Those skilled in the art will recognize that many variations are possible within the spirit and scope of the subject matter, which is intended to be defined by the following claims—and their equivalents—in which all terms are meant in their broadest reasonable sense unless otherwise indicated.

What is claimed is:

1. A computer system comprising:
a printed circuit board (PCB) that includes a first external interface for memory connection thereto, the first external interface employs a first memory protocol;
an extension circuit board that includes a second external interface for memory connection thereto and a third external interface, wherein the second external interface employs a second memory protocol different from the first memory protocol; and
at least one translator module connectable to the first external interface of the PCB and the third external interface of the extension circuit board to provide translation between the first and second memory protocols.

2. The computer system of claim 1, wherein the first memory protocol is a serial memory protocol, and the second memory protocol is a parallel memory protocol.

3. The computer system of claim 2, wherein the serial memory protocol is a fully-buffered dual in-line memory module (FB-DIMM) protocol, and the parallel memory protocol is one of a double data rate (DDR), DDR2, and DDR3 synchronous dynamic random access memory (SDRAM).

4. The computer system of claim 1, wherein the first external interface includes a plurality of memory connectors of the first memory protocol, each of the plurality of memory connectors operates to connect one of:
a) a memory module of the first memory protocol, and
b) the at least one translator module.

5. The computer system of claim 1, wherein the first external interface includes a plurality of memory connectors of the first memory protocol, a first one of the plurality of memory connectors operates to connect a memory module of the first memory protocol, and a second one of the plurality of memory connectors operates to connect the at least one translator module.

6. The computer system of claim 1, wherein the at least one translator module is substantially vertically connected to both the PCB and the extension circuit board, and the extension circuit board is arranged substantially parallel to the PCB.

7. The computer system of claim 1, wherein the at least one translator module is connected to both the PCB and the extension circuit board on a plane that intersects the substantially parallel planes of the PCB and the extension circuit board.

8. The computer system of claim 5, wherein the extension circuit board 15 includes at least one mechanism for securing the extension circuit board to the PCB.

9. The computer system of claim 1, wherein:
the first external interface includes a first and second memory connectors of the first memory protocol;
the at least one translator module is connected to the first memory connector; and
the computer system further includes a memory module of the first memory protocol connected to the second memory connector.

10. The computer system of claim 9, wherein the at least one translator module is removable from the first memory connector to enable connection of a second memory module of the first memory protocol to the first memory connector.

11. The method of claim 1, wherein the at least one translator module is removable from the PCB and the extension circuit board.

12. A computer system comprising:
a motherboard that includes thereon a computer processor and first memory connectors for connection of one or more memory modules thereto to provide computer-executable codes for execution by the computer processor, the first memory connectors employ a serial memory protocol; and
a translator device structure that is modular to the rest of the computer system such that it is removable from the computer system, the translator device structure includes,
a) a mezzanine board arranged in proximity and substantially parallel to the motherboard, the mezzanine board includes second memory connectors for connection of one or more memory modules thereto and third memory connectors, the second and third memory connectors employ a parallel memory protocol; and
b) a translator module substantially orthogonally connected to one of the first memory connectors on the motherboard and one of the third memory connectors on the mezzanine board to provide translation between the serial and parallel memory protocols.

13. The computer system of claim 12, further comprising:
a first memory module of the parallel memory protocol inserted in one of the second memory connectors on the mezzanine board;
wherein the translator module provides translation of the parallel memory protocol of the first memory module for the motherboard so that the motherboard is operable to use the first memory module for data read and write to the first memory module.

14. The computer system of claim 13, further comprising:
a second memory module of the serial memory protocol inserted in one of the first memory connectors on the motherboard for use by the motherboard.

15. The computer system of claim 13, wherein the first memory module is one of a double data rate (DDR), DDR2, and DDR3 dynamic random access memory (DRAM).

16. The computer system of claim 14, wherein the second memory module is a fully-buffered dual in-line memory module (FB-DIMM).

17. A process for modifying memory-protocol implementation in a computer system comprising:
providing the computer system that includes a printed circuit board (PCB) with a computer processor and a first memory connector for serial protocol memory implementation thereon to provide computer-executable codes for execution by the computer processor;
providing a translator device structure separately from the computer system, the translator device structure includes a translator module connectable and removable from an extension circuit board, the extension circuit board includes a second memory connector for parallel protocol memory implementation thereon; and
performing an upgrade of the serial memory implementation within the PCB to the parallel protocol memory implementation outside the PCB through employment of the translator device structure in the computer system and the translator module therein to provide translation between the serial and parallel protocol memory implementations.

18. The process of claim 17, wherein the step of performing the upgrade comprises:
providing a substantially orthogonal connection of the translator module to the first memory connector on the PCB;
providing a substantially orthogonal connection of the extension circuit board to the translator module;
providing a connection of a memory module with parallel memory protocol implementation therein to the second memory connector on the extension circuit board; and
providing a translation of the parallel protocol memory implementation of the memory module to the serial protocol memory implementation for employment by the PCB.

19. The process of claim 18, wherein the parallel protocol memory implementation includes one of double data rate (DDR), DDR2, and DDR3 dynamic random access memory (DRAM) implementation; and the serial protocol memory implementation second memory module is a fully-buffered dual in-line memory module (FB-DIMM) implementation.

20. The process of claim 17, further comprising:
removing the upgrade by removing the translator device structure from the computer system.
